(19) United States
(12) Patent Application Publication
(10) Pub. No.: US 2003/0095385 A1
(43) Pub. Date: May 22, 2003

(54) Communication distribution system with coaxial cable distrbution hub

(76) Inventors: Ronny W. Holliday, Wilkinson, IN (US); Jeffrey A. Roach, Brownsburg, IN (US)

Correspondence Address: John V. Moriarty, Woodard, Emhardt, Naughton, Moriarty and McNett, Bank One Center/Tower, 111 Monument Circle, Suite 3700, Indianapolis, IN, 46204-5137, US

(21) Appl. No.: 10/006,442

(22) Filed: Nov. 20, 2001

(51) Int. Cl. H05K 7/00

(52) U.S. Cl. 361/728

(57) ABSTRACT

A communication distribution system having a coaxial cable distribution hub. A control panel box includes a plurality of removable modules selectively connectable to incoming phone lines, cable lines, antenna and satellite input lines and a computer CPU input line. The modules are arranged to allow the incoming lines to be selectively connectable to various rooms in a building. The coaxial cable distribution hub includes intermediate coaxial cable room connectors. An indicia wall next to the intermediate coaxial cable connectors includes a room chart for marking and assigning a particular room outlet with the coaxial connector.

### BACKGROUND OF THE INVENTION

The present invention relates generally to the field of control panels and boxes for routing communications data.

### DESCRIPTION OF THE PRIOR ART

Communications data is delivered via different modes including by phone line, coaxial cable, various types of antennas and by satellite dish. It is customary to install a variety of connectors or jacks within the various rooms of a building to receive the incoming communication data. In many cases, each room outlet is hardwired to a particular source of data input to the building. Flexibility is therefore lost when the data mode of delivery is changed and when it is desired to route the data to a different room outlet. Communication distribution systems have been developed that include a central control panel connected to the various data input lines to the building as well as to the various room outlets within the building. In order to increase the flexibility of the control panel, removable data modules are provided and are commercially available thereby allowing the control panels to be customized to the particular application. One such removable data module is disclosed in U.S. Pat. No. 6,266,250.

In order to customize a particular communications control panel to building requirements, it is necessary to route the various cables within the panel between separate modules as well as provide for proper routing of the incoming and outgoing cables and wires. Routing of coaxial cables becomes particularly difficult due to the cable diameter and the relative stiffness of the cables. Data is conveyed via the coaxial cables from antennas, satellite dishes, and television cable company lines. In many cases, the incoming signals must be split and combined in order to provide the proper signal at a particular room connector.

In order to increase the flexibility of such communication data control panels, we have designed a coaxial cable distribution hub having intermediate coaxial cables oriented in such a manner to ease the connection with the incoming lines. The incoming lines may be selectively connected to the intermediate coaxial connectors for changing the type of data originally assigned to a particular room outlet connector. Thus, if it is desired to change a room outlet connector originally assigned to receive data from a satellite dish to instead receive data from an antenna, then the intermediate connector may be disconnected from the incoming satellite dish data line and connected to the particular data line, such as, an incoming antenna data line. Further, the intermediate coaxial connectors are aligned at an acute angle relative to the control box mounting plane thereby allowing the coaxial cables connected thereto to extend generally parallel to the mounting plane without twisting around and under various items as is customary with the prior control panels.

### SUMMARY OF THE INVENTION

One embodiment of the present invention is a communication distribution system for a building having rooms with outlets. A telephone master hub is mounted in a housing and includes a telephone line input and a plurality of telephone line output connectors. An Ethernet switch is mounted in the housing and has a computer input connector and a plurality of peripheral outlet connectors. A telephone/computer data hub has telephone/computer room connectors assigned to and connectable to the various outlets in the building. The room connectors are removably and selectably connectable to the telephone line output connectors and to the peripheral outlet connectors. A coaxial cable splitter hub is mounted in the housing and has a coaxial cable input connector and a plurality of coaxial cable output connectors. An antenna/satellite switch has antenna/satellite input connectors and a plurality of antenna/satellite output connectors. A coaxial cable distribution hub is mounted in the housing and has a plurality of coaxial cable room connectors. The coaxial cable room connectors are assigned to and connectable to various outlets in the building. The coaxial cable room connectors are removably and selectably connectable to the coaxial cable output connectors and to the antenna/satellite output connectors.

It is an object of the present invention to provide a new and improved communication distribution system.

A further object of the present invention is to provide a communication data control panel having a hub for distributing coaxial cable data.

In addition, it is an object of the present invention to provide a coaxial cable distribution hub for removably mounting to a communication distribution box to selectively route data from coaxial cable to room outlets in a building.

Related objects and advantages of the present invention will be apparent from the following description.

### BRIEF DESCRIPTION OF THE DRAWINGS

FIG. 1 is a plan view of a communication distribution control panel incorporating the present invention.

FIG. 2 is an enlarged top view looking in the direction of arrows 2-2 of the splitter.

FIG. 3 is an enlarged fragmentary cross-sectional view of the coaxial cable distribution hub taken along a line and viewed in the direction of the arrows 3-3 of FIG. 1.

FIG. 4 is an enlarged cross-sectional view taken along a line and viewed in the direction of the arrows 4-4 of FIG. 3 showing the mounting arrangement of the intermediate coaxial connectors.

FIG. 5 is an enlarged cross-sectional view taken long a line and viewed in the direction of the arrows 5-5 of FIG. 3 illustrating the marking indicia corresponding to the connectors of FIG. 4.

### DESCRIPTION OF THE PREFERRED EMBODIMENT

For the purposes of promoting an understanding of the principles of the invention, reference will now be made to the embodiment illustrated in the drawings and specific language will be used to describe the same. It will nevertheless be understood that no limitation of the scope of the invention is thereby intended, such alterations and further modifications in the illustrated device, and such further applications of the principles of the invention as illustrated therein being contemplated as would normally occur to one skilled in the art to which the invention relates.

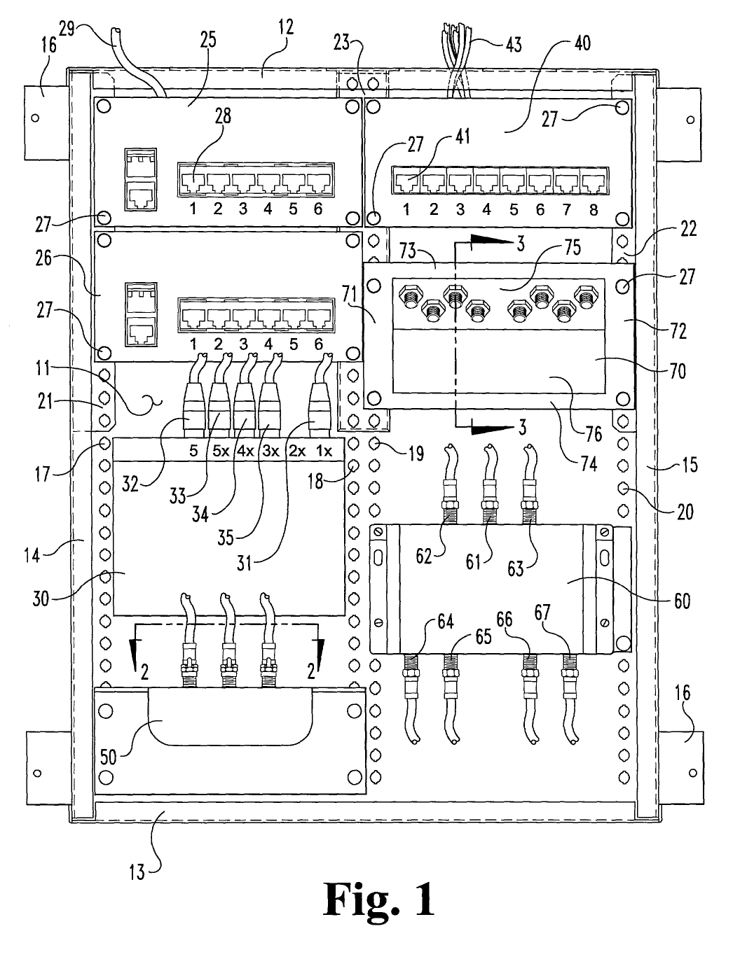

Referring now more particularly to FIG. 1, there is shown a control box having a back wall 11 fixedly joined to a pair of end walls 12 and 13 and a pair of side walls 14 and 15 in a rectangular configuration. Walls 12-15 extend perpendicularly outward from back wall 11 forming a cavity into which various data modules, cables and wiring may be provided. Four mounting flanges 16 are fixedly mounted to side walls 14 and 15 and extend outwardly therefrom to allow the control panel to be mounted to a building wall. The front of the control panel may be provided with a cover door.

In the preferred embodiment shown in FIG. 1, wall 11 is provided with four vertical rows 17-20 of holes extending through the wall. The holes allow for the removable mounting of various data modules. A pair of right angle flanges 21 and 22 are mounted respectively to side wall 14 and 15 and are spaced apart from back wall 11 to allow the wiring and cabling from each data module to be spaced between the data module and the back wall. The third mounting flanges 23 is spaced outwardly from back wall 11 and is attached at one end to wall 12 and at its opposite end to a bracket securing wall 23 to wall 11. Mounting flanges 21, 22 and 23 are spaced apart from back wall 11 and thereby provide a mounting plane upon which data modules may be secured.

A telephone master hub module 25 and a telephone expansion hub module 26 are removably mounted to and atop mounting flanges 21 and 23. Commercially available quick disconnect connectors 27 are mounted to the outwardly extending flanges of hubs 25 and 26 which overlap and rest atop mounting flanges 21 and 23 with connector 27 being removably extendable through holes provided in flanges 21 and 23. Telephone master hub 25 and telephone expansion hub 26 are commercially available and are used to route the incoming phone data to a variety of outlets.

Telephone master hub 25 includes six outlet ports 28 which are shown in FIG. 1 as numbered sequentially from 1-6. The particular telephone master hub forming part of the prior art is commercially available from Dynaflex, Inc., 1735 W. 18^{th} Street, Indianapolis, Ind. 46202 under Model No. D4000 and is designed to accommodate four incoming lines via line 29 connected to the back of the module and having six output ports 28.

Telephone expansion hub 26 is also commercially available from Dynaflex, Inc. and forms part of the prior art. In the embodiment shown in the drawing, the telephone expansion hub available under Model No. D4100 likewise has four incoming phone lines and six output ports and is connectable to the telephone master hub.

A conventional Ethernet switch 30 is fixedly mounted to back wall 11 and has a computer input connector 31 and four peripheral outlet connectors 32-35. Connector 31 is connected to a central computer CPU whereas outlet connectors 32-35 are connectable to peripheral equipment, such as, printers and terminals located in various rooms in the building.

A telephone computer data hub 40 includes a pair of outwardly extending flanges overlapping and resting atop mounting flanges 23 and 22. Conventional quick disconnect connectors 27 are mounted thereto for securing module 40 to flanges 22 and 23 which are in spaced relationship to the back wall 11. Module 40 is provided with eight inlet ports 41 sequentially numbered on the face of the module from 1-8. Thus, in the embodiment shown in FIG. 1, phone line outputs 1-4 of telephone master hub 25 are connected by lines to inlet ports 1-4 of data hub 40. Likewise, the peripheral outlet connectors 32-35 of Ethernet switch 30 are connected by lines to inlet ports 5-8 of module 40.

Outlet lines contained in bundle 43 are connected to each port 1-8 and extend in the building to the particular room outlet. Thus, each port 1-8 is assigned to a particular outlet in a particular room in the building. Thus, it is possible to connect the incoming phone lines from ports 1-4 of the telephone master hub 25 as well as the data from peripheral connectors 32-35 to a particular port 1-8 of distribution hub 40 depending upon the desired data connection. The wires of bundle 43 may be hard wired to the outlets of ports 1-8 whereas the lines extending from hub 25 and Ethernet switch 30 to ports 1-8 of hub 40 include a conventional connectors which may be removably and selectively connectable to ports 1-8 of hub 40. The end wall 12 of panel 10 is provided with holes through which the incoming and outgoing lines, such as bundle 43, extend.

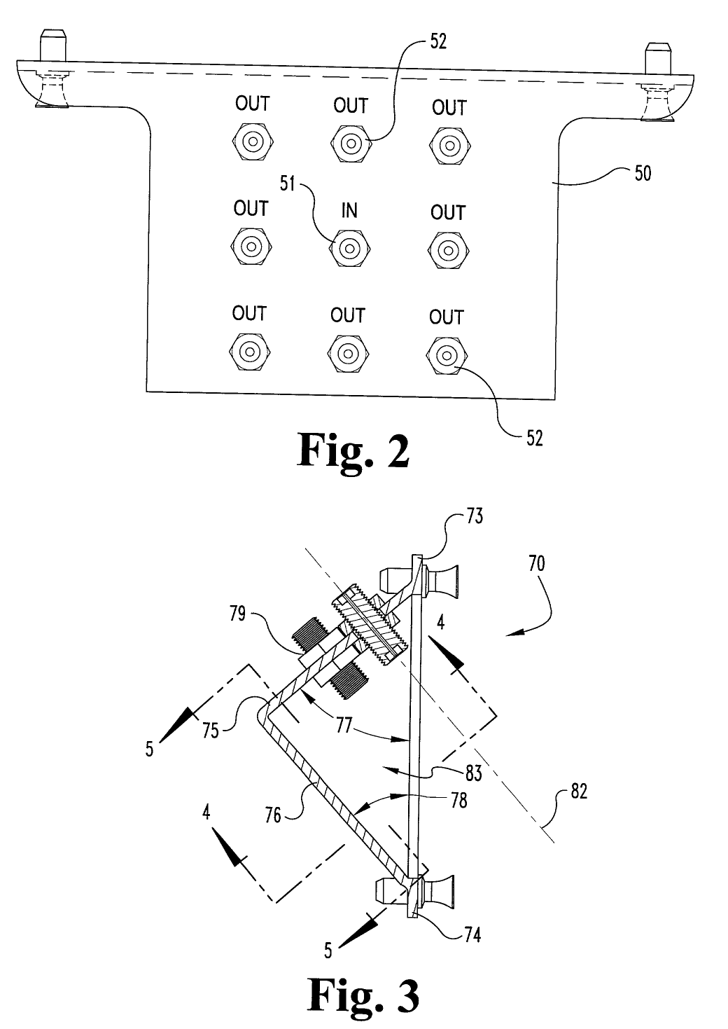

A coaxial cable splitter hub 50 is fixedly mounted to wall 11 and extends perpendicularly and outwardly therefrom. In the embodiment shown in FIG. 2, splitter hub 50 includes nine conventional coaxial cable connectors with one connector 51 assigned to receive the incoming cable line, such as, from the TV cable company whereas the remaining eight connectors 52 are assigned to distribute the split incoming signal to various locations. A conventional splitter module (not shown) is fixedly mounted to and beneath the top wall of splitter 50 and is operable to split the incoming signal on connector 51 into eight output signals on connectors 52. The coaxial cable output connectors 52 extend parallel to back wall 11.

An antenna/satellite switch 60 is fixedly mounted to back wall 11 and has an antenna input connector 61 and two satellite dish input connectors 62 and 63. The switch further has four antenna/satellite output connectors 64-67. In the embodiment of FIG. 1, switch 60 is a voltage-controlled, multi-switch operable over the range of 40 to 2150 MHz. Such a multi-switch is commercially available under Model 8M 734 from PM International Ltd., 11 Taylor Road, Edison, N.J. 08810.

The coaxial cable distribution hub 70 (FIG. 3) has a pair of side flanges 71 and 72 overlapping and resting atop mounting flanges 23 and 22 and include quick disconnect connectors 27 for removably mounting the hub to the row of holes provided on flanges 23 and 22. Flanges 71 and 72 are integrally connected to end flanges 73 and 74 and, in turn, are integrally connected to a coaxial cable room connector mounting wall 75 and a marking indicia wall 76. Walls 75 and 76 are integrally connected together at a right angle with the outer ends of walls 75 and 76 connected respectively to flanges 73 and 74. Flanges 71-74 are parallel and define a mounting plane parallel to the back wall 11 of the control panel. Wall 75 (FIG. 3) is arranged at an acute angle 77 relative to the mounting plane defined by flanges 71-74. Likewise, wall 76 is arranged at an acute angle 78 relative to the mounting planes defined by flanges 71-74. In the embodiment depicted in FIG. 3, angle 77 is approximately 60 degrees whereas angle 78 is approximately 30 degrees.

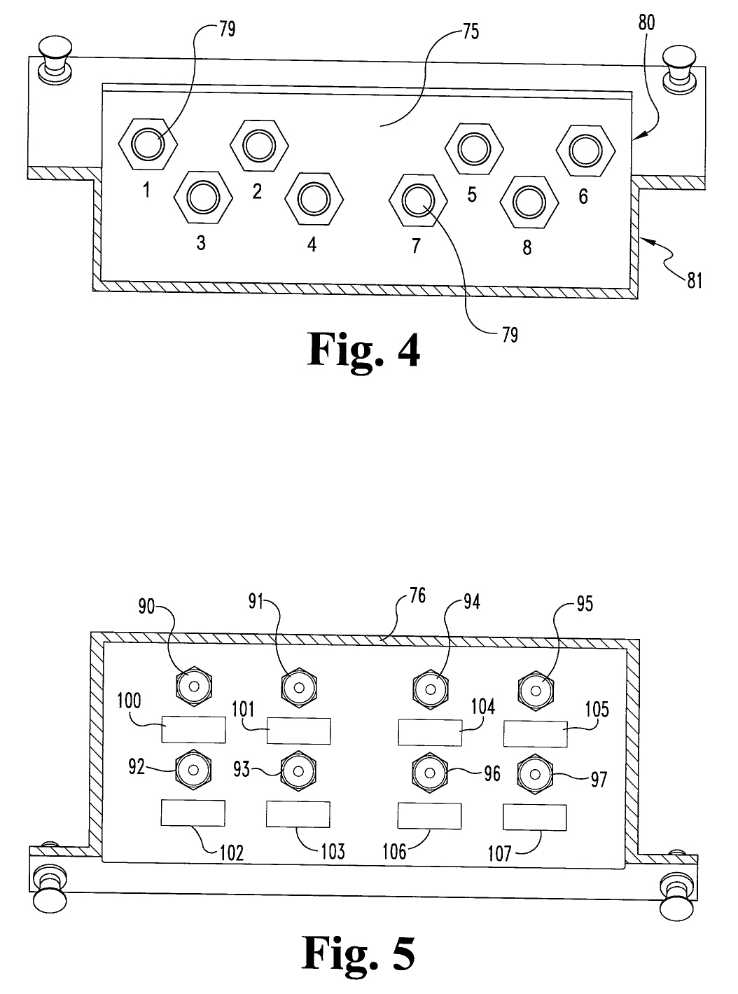

Eight conventional coaxial connectors 79 are mounted to wall 75 and are arranged in an upper row 80 (FIG. 4) and a lower row 81. The connectors 79 in row 80 are offset vertically relative to the connectors 79 in row 81. Each connector has a longitudinal axis 82 (FIG. 3) extending parallel to wall 76. Wall 75 and 76 are sufficiently deep and extend away from the mounting plane farmed by flanges 71-74 forming recess 83 to enable a person's hand to connect cables to connectors 79.

The coaxial cables connected to the outputs of connectors 79 are assigned to and are connectable to various outlets in the rooms in a building. The inputs of connectors 79 are removably and selectively connectable to the coaxial cable output connectors of module 30 and the antenna/satellite output connectors of switch 60. In the embodiment of FIG. 1, the coaxial cable output connectors 32-35 are removably connected to room connectors 79 identified as 1-4 in FIG. 4. The four antenna/satellite output connectors 64-67 are removably and selectively connectable to the coaxial cable connectors 79 identified by number 5-8 of FIG. 4. The coaxial cables extending from the connectors 32-35 have female internally threaded connectors at their distal ends to matingly receive the external threaded male coaxial connectors identified as 1-4 in FIG. 4. Likewise, the coaxial cables connected to connectors 64-67 have at their outer distal ends internally threaded female connectors in meshing engagement with connectors 5-8 of FIG. 4. The coaxial cables extending from the output connectors 32-35 to connectors 79 may extend generally parallel to back wall 11 and the mounting plane formed by flanges 71-74 until the cables reach connectors 79 at which point the cables may be bend slightly downward to connect to the cable room connectors 79. Axis 82 of each connector 79 is arranged at an acute angle relative to back wall 11 facilitating the ease of connection with the cables.

Indicia wall 76 includes a separate depiction or illustration, such as an end view of a coaxial cable connector for each connector 79 mounted to wall 75. Thus, depictions 90-97 are provided on wall 76 corresponding to the eight connectors identified as 1-8 in FIG. 4. Located beneath each depiction 90-97 is a rectangular block in which the user may mark the particular room assigned to the particular room coaxial connector. Thus, rectangular blocks 100-107 are located beneath respectively connector depictions 90-97. In the preferred embodiment, wall 76 is provided with a markable surface, such as, a decal having depictions 90-97 and rectangles 100-107 printed thereon. As an example of the room assignment chart shown in FIG. 5, the user may mark in block 101 the letters “LB” thereby providing a reminder that depiction 91 corresponding to room coaxial connector identified as 2 in FIG. 4 is connected to the outlet connector located in the library.

While the invention has been illustrated and described in detail in the drawings and foregoing description, the same is to be considered as illustrative and not restrictive in character, it being understood that only the preferred embodiment has been shown and described and that all changes and modifications that come within the spirit of the invention are desired to be protected.

What is claimed is:

1. A communication distribution system for a building having rooms with outlets comprising:
a housing with a back wall, said housing having mounts for securing said housing within a building;
a telephone master hub mounted in said housing, said telephone master hub including a telephone line input and a plurality of telephone line output connectors;
an Ethernet switch mounted in said housing, said switch having a computer input connector and a plurality of peripheral outlet connectors;
a telephone/computer data hub having telephone/computer room connectors assigned to and connectable to various outlets in rooms in said building, said room connectors removably and selectably connectable to said telephone line output connectors and to said peripheral outlet connectors; and,
a coaxial cable splitter hub mounted in said housing, said splitter hub having a coaxial cable input connector and a plurality of coaxial cable output connectors;
an antenna/satellite switch having antenna/satellite input connectors and a plurality of antenna/satellite output connectors; and,
a coaxial cable distribution hub mounted in said housing, said coaxial cable distribution hub having a plurality of coaxial cable room connectors each with a longitudinal axis, said coaxial cable room connectors assigned to and connectable to various outlets in rooms in said building, said coaxial cable room connectors removably and selectably connectable to said coaxial cable output connectors and to said antenna/satellite output connectors.

2. The communication distribution system of claim 1 wherein:
said housing includes a plurality of supports; and,
said coaxial cable distribution hub includes a main body with a pair of flanges positionable atop and securable to said supports, said coaxial cable distribution hub further includes a mounting wall with said coaxial cable room connectors mounted thereon and orienting said longitudinal axis of said coaxial cable room connectors acutely relative to said back wall.

3. The communication distribution system of claim 2 wherein:
said main body further includes an indicia wall that extends between said flanges and from said mounting wall, said indicia wall includes a room assignment chart to assign rooms in said building to each of said coaxial cable room connectors.

4. The communication distribution system of claim 2 wherein:
said splitter hub includes a splitter hub wall that extends perpendicularly outwardly from said back wall, said coaxial cable output connectors extend parallel to said back wall.

5. The communication distribution system of claim 4 wherein:
said telephone master hub and said telephone/computer data hub are removably mounted to said supports; said splitter hub, said antenna/satellite switch and said distribution hub are mounted to said back wall.

6. The communication distribution system of claim 5 and further comprising:
a plurality of coaxial cables selectively and removably connectable to said coaxial cable output connectors and said coaxial cable room connectors depending upon which location in said building is to be provided with data from said cable input connector; and.
a plurality of coaxial cables selectively and removably connectable to said antenna/satellite output connectors and said coaxial room connectors depending upon which location in said building is to be provided with data from said antenna/satellite input connectors.

7. A communication distribution system to allow selective routing of coaxial data to outlets in rooms within a building comprising:
a housing with a back wall, said housing having means for securing said housing within a building;
a coaxial cable splitter hub mounted in said housing, said splitter hub having a coaxial cable input connector and a plurality of coaxial cable output connectors;
an antenna/satellite switch having antenna/satellite input connectors and a plurality of antenna/satellite output connectors; and,
a coaxial cable distribution hub mounted in said housing, said coaxial cable distribution hub having a plurality of coaxial cable room connectors each with a longitudinal axis, said coaxial cable room connectors assigned to and connectable to various outlets in rooms in said building, said coaxial cable room connectors removably and selectably connectable to said coaxial cable output connectors and to said antenna/satellite output connectors to allow selective routing of coaxial data to the rooms.

8. The communication distribution system of claim 7 wherein:
said housing includes a plurality of supports; and,
said coaxial cable distribution hub includes a main body with a pair of flanges positionable atop and securable to said supports, said coaxial cable distribution hub further includes a mounting wall with said coaxial cable room connectors mounted thereon and orienting said longitudinal axis of said coaxial cable room connectors acutely relative to said back wall.

9. The communication distribution system of claim 8 wherein:
said main body includes an indicia wall connected to said mounting wall, said indicia wall includes a room assignment chart to assign rooms in said building to each of said coaxial cable room connectors on said mounting wall.

10. The communication distribution system of claim 9 and further comprising:
a plurality of coaxial cables selectively and removably connectable to said coaxial cable output connectors and said coaxial cable room connectors depending upon which room in said building is to be provided with data from said cable input connector; and.
a plurality of coaxial cables selectively and removably connectable to said antenna/satellite output connectors and said coaxial room connectors depending upon which room in said building is to be provided with data from said antenna/satellite input connectors.

11. The communication distribution system of claim 10 wherein:
said indicia wall includes a separate depiction corresponding to each of said coaxial room connectors with said room chart having a separate indicia space for marking thereon the room associated with each of said separate depiction assigned to each of said coaxial room connectors.

12. The communication distribution system of claim 11 wherein:
said splitter hub includes a wall arranged perpendicularly relative to said back wall with said coaxial cable input connector and said coaxial cable output connectors mounted thereon allowing coaxial cables attached thereto to extend generally parallel to said back wall between said splitter hub to said coaxial cable distribution hub where connected to said coaxial cable room connectors.

13. A coaxial cable distribution hub for removably mounting to a communication distribution box for selectively routing data from coaxial cables to room outlets in a building comprising:
a module having mounting flanges for mounting in a building and further having a plurality of coaxial cable room connectors each with a longitudinal axis, said coaxial cable room connectors assigned to and connectable to various room outlets in a building, said coaxial cable room connectors removably and selectively connectable to coaxial cables to allow selective routing of coaxial data from said cables to the room outlets, said module having a mounting wall with said coaxial cable room connectors mounted thereon and orienting said longitudinal axis of said coaxial cable room connectors acutely relative to said mounting flanges.

14. The hub of claim 13 wherein:
said module includes an indicia wall connected to said mounting wall, said indicia wall includes a room assignment chart to assign room outlets in said building to each of said coaxial cable room connectors on said mounting wall.

15. The hub of claim 14 and further comprising:
a plurality of coaxial cables selectively and removably connectable to said coaxial cable room connectors depending upon which room outlet in said building is to be provided with data from said coaxial cables.

16. The hub of claim 15 wherein:
said indicia wall includes a separate depiction corresponding to each of said coaxial room connectors with said room chart having a separate indicia space for marking thereon the room outlet associated with each of said separate depiction assigned to each of said coaxial room connectors.
